(19) United States
(12) Patent Application Publication
(10) Pub. No.: US 2026/0219460 A1
(43) Pub. Date: Jul. 30, 2026

(54) OPTICAL COUPLING LENS MODULE AND OPTICAL FIBER CONNECTOR

(71) Applicant: CONNPRO INDUSTRIES INC, New Taipei City (TW)

(72) Inventors: Chien Te Lin, New Taipei City (TW); Chien Yu Chiu, New Taipei City (TW); Ming Lin Chan, New Taipei City (TW)

(73) Assignee: CONNPRO INDUSTRIES INC, New Taipei City (TW)

(21) Appl. No.: 19/456,998

(22) Filed: Jan. 22, 2026

Related U.S. Application Data
(60) Provisional application No. 63/748,984, filed on Jan. 24, 2025.

(51) Int. Cl. G02B 6/42; G02B 6/38; H05K 7/20

(52) U.S. Cl. CPC G02B 6/4214; G02B 6/3882; G02B 6/421; G02B 6/4231; G02B 6/4244; G02B 6/4256; G02B 6/428; H05K 7/205

(57) ABSTRACT

An optical coupling lens module includes a body, a first convex lens, a light reflecting element, and a second convex lens. The body has an inner bottom surface, a positioning protrusion, and a docking surface. The positioning protrusion protrudes from the docking surface to dock with a fiber jumper. The docking surface includes a first abutting surface and a second abutting surface distinct from each other to match the fiber jumper. The positioning protrusion occupies different portions of the first and the second abutting surfaces. The first convex lens is disposed on an inner bottom surface, the light reflecting element is disposed inside the body, and the second convex lens is disposed at the docking surface. A light source generates a light beam transmitted to the fiber jumper via the first convex lens, the light reflecting element, and the second convex lens sequentially. An optical fiber connector is also provided.

### CROSS-REFERENCE TO RELATED APPLICATION

This application claims the priority benefit of U.S. provisional application serial no. 63/748,984, filed on January 24, 2025. The entirety of the above-mentioned patent application is hereby incorporated by reference herein and made a part of this specification.

### BACKGROUND

### Technical Field

This disclosure relates to an optical coupling lens module and an optical fiber connector.

### Related Art

Optical fiber communication systems use optical signals for information transmission, which are not affected by electromagnetic interference and may avoid problems such as power loss and transmission attenuation faced during the transmission of traditional electrical signals through copper wires, making optical fiber connectors widely used in network communications.

However, during transmission in optical fiber communication systems, the optical fiber connector heats up due to energy consumption, and the temperature generated by the heating components inside the optical fiber connector must be dissipated. Furthermore, as parallel optical transceiver modules achieve ultra-high speed and large capacity data transmission by adopting high density multi-channel designs, although this provides more advantages in communication, it also makes the aforementioned heat dissipation problem more severe. In particular, when optical fiber communication systems perform high-speed transmission, the temperature inside the optical fiber connector rises rapidly and generates a large amount of heat, thereby affecting the stability and reliability of the optical fiber connector operation.

Based on the above, how to provide corresponding heat dissipation means for high density configured optical fiber connectors is indeed a subject that relevant technical personnel need to consider and solve.

### SUMMARY

The disclosure provides an optical coupling lens module and an optical fiber connector, to have both better space configuration density rate and heat dissipation effect.

The optical coupling lens module of the disclosure includes a body, a first convex lens, a light reflecting element, and a second convex lens. The body has an inner bottom surface, a positioning protrusion, and a docking surface, wherein the positioning protrusion protrudes from the docking surface to dock with a fiber jumper. The docking surface includes a first abutting surface and a second abutting surface different from each other to adapt to the fiber jumper. The positioning protrusion occupies a portion of the first abutting surface and occupies a portion of the second abutting surface. The first convex lens is disposed on the bottom surface to receive a first light beam from a light source and convert the first light beam to a parallel light beam. The light reflecting element is disposed in the body to receive and transmit the parallel light beam. The second convex lens is disposed on the docking surface to receive the parallel light beam and convert the parallel light beam to a second light beam and transmit the second light beam to a fiber core of the fiber jumper.

The optical fiber connector of the disclosure includes a metal housing and two optical coupling components. Each of the optical coupling components includes an optical coupling lens module, a light source, a fiber jumper, and a circuit board component. The optical coupling lens module includes a body, a first convex lens, a light reflecting element, and a second convex lens. The body has an inner bottom surface, a positioning protrusion, and a docking surface, wherein the positioning protrusion protrudes from the docking surface, the docking surface includes a first abutting surface and a second abutting surface different from each other, and the positioning protrusion occupies a portion of the first abutting surface and occupies a portion of the second abutting surface. The first convex lens is disposed on the inner bottom surface, the light reflecting element is disposed in the body, and the second convex lens is disposed on the docking surface. The light source and the body are respectively disposed on the circuit board component, wherein the two optical coupling lens modules of the two optical coupling components are adjacent to each other and away from the metal housing, and the two circuit board components of the two optical coupling components are opposite to each other with the two optical coupling lens modules therebetween to be adjacent to the metal housing. The light source generates light beams sequentially transmitted through the first convex lens, the light reflecting element, and the second convex lens to the fiber jumper.

Based on the above, the body of the optical coupling lens module provides a first abutting surface and a second abutting surface different from each other on its docking surface having the positioning protrusion, to facilitate adapting to different angle interfaces of different fiber jumpers. Meanwhile, for the optical fiber connector, particularly for the space configuration in a double-layer circuit board stacking state, the two optical coupling lens modules of the optical coupling components are adjacent to each other and away from the metal housing, and the two circuit board components of the optical coupling components are opposite to each other with the two optical coupling lens modules therebetween to be adjacent to the metal housing. This provides better space utilization.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of an optical fiber connector according to an embodiment of the disclosure.

FIG. 2 is a schematic view of partial components of the optical fiber connector of FIG. 1.

FIG. 3 is a partial schematic view of an optical coupling component.

FIG. 4A is an assembly schematic view of partial components of an optical coupling lens module and a fiber jumper.

FIG. 4B depicts the optical coupling lens module from another viewing angle.

FIG. 5 is a cross-sectional view of the optical coupling component.

FIG. 6A is a partial cross-sectional view of the optical fiber connector.

FIG. 6B depicts the optical fiber connector from another viewing angle.

FIG. 7A depicts an optical fiber connector according to another embodiment of the disclosure.

FIG. 7B is a side view of partial components of the optical fiber connector of FIG. 7A.

FIG. 8 is a partial schematic view of an optical coupling component according to another embodiment of the disclosure.

### DESCRIPTION OF THE EMBODIMENTS

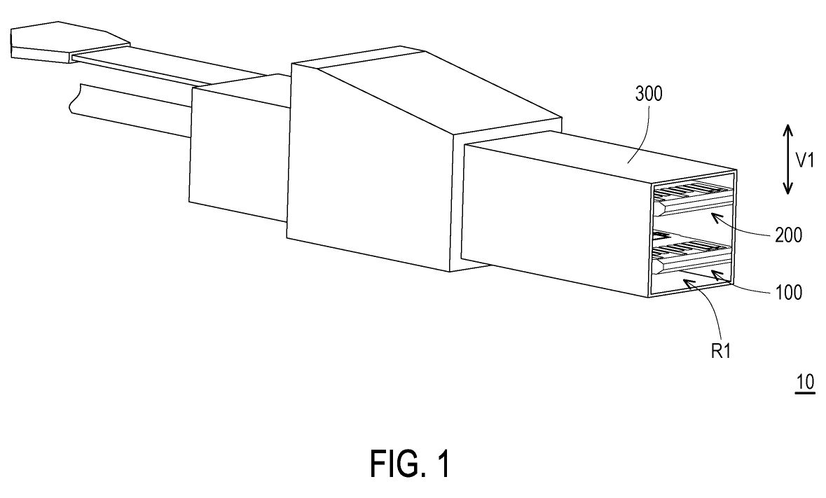

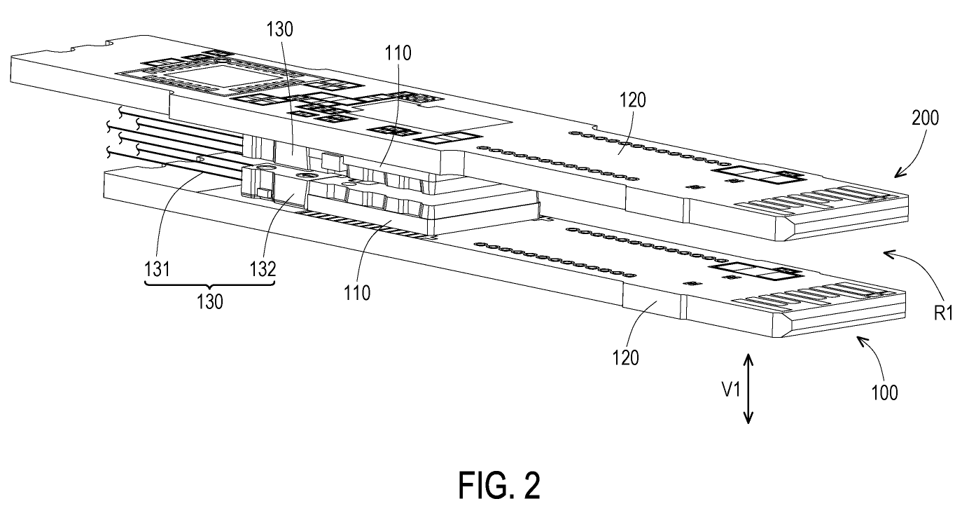

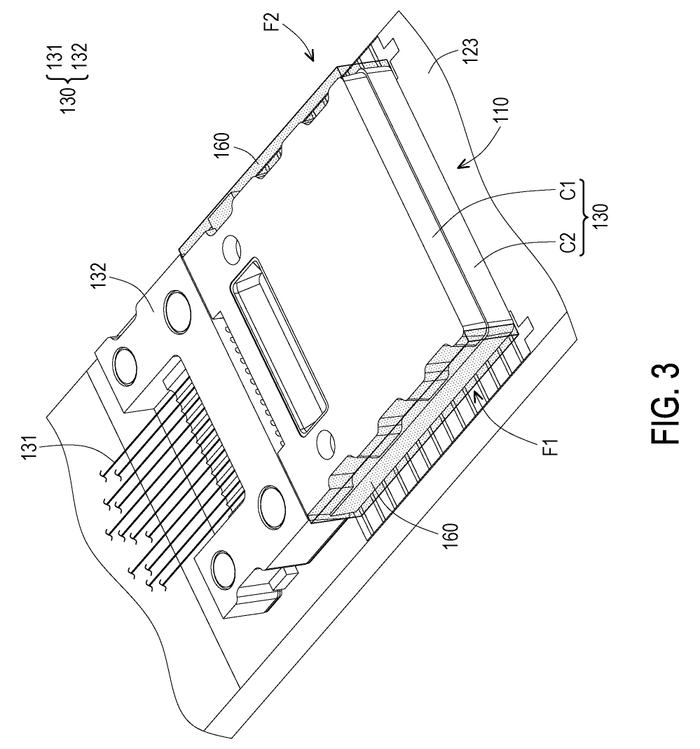

FIG. 1 is a schematic view of an optical fiber connector according to an embodiment of the disclosure. FIG. 2 is a schematic view of partial components of the optical fiber connector of FIG. 1. FIG. 3 is a partial schematic view of an optical coupling component. Please refer to FIGS. 1 to FIG. 3 simultaneously. In this embodiment, an optical fiber connector 10, this embodiment takes Mini-SAS HD (Mini Serial Attached SCSI High Density) as an example, which is an evolved version of the SAS (Serial Attached SCSI) storage interface, providing higher port density and transmission rate (such as 12Gb/s or 14Gb/s), commonly used in data centers and enterprise-level storage systems. Here, the optical fiber connector 10 includes a metal housing 300 and two optical coupling components 100 and 200. The optical coupling components 100 and 200 are configured within the metal housing 300 and have the same component composition.

Here, the optical coupling component 100 is taken as an example for subsequent description. The optical coupling component 100 includes a circuit board component 120, an optical coupling lens module 110 and a fiber jumper 130, wherein the optical coupling lens module 110 and the fiber jumper 130 are respectively configured on the same surface of the circuit board component 120. Referring to FIGS. 1 and FIG.2 simultaneously, and taking a docking side R1 of the optical fiber connector 10 (for docking with another connector) as a reference, the stacking method adopted in this embodiment is to have the two optical coupling lens modules 110 of the two optical coupling components 100 and 200 adjoin each other to be away from the metal housing 300 in a longitudinal direction V1 (arrangement direction), and the two circuit board components 120 of the two optical coupling components 100 and 200 are opposite to each other with the two optical coupling lens modules 110 therebetween to be adjacent to the metal housing 300. The effect generated by the configuration will be further described subsequently.

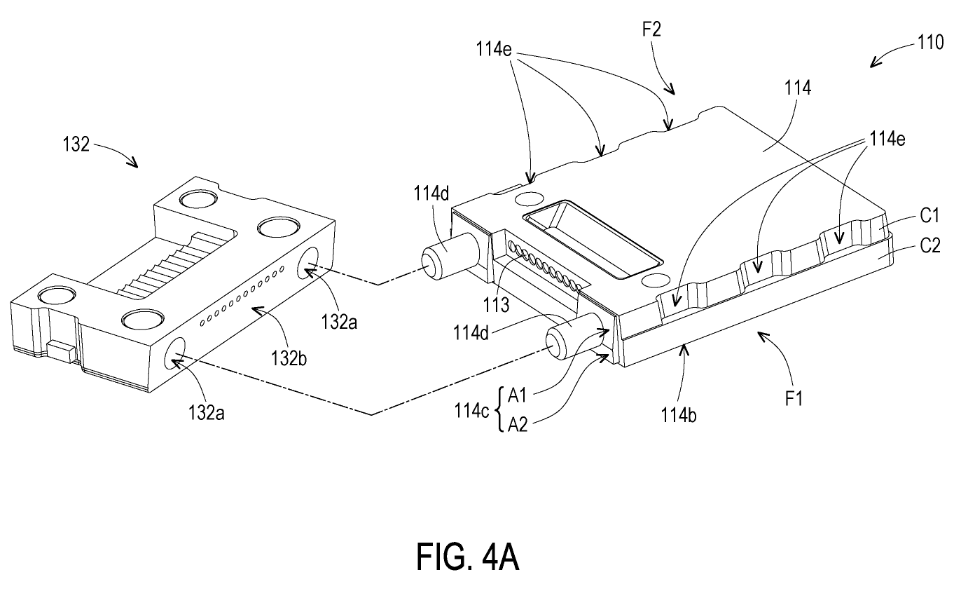

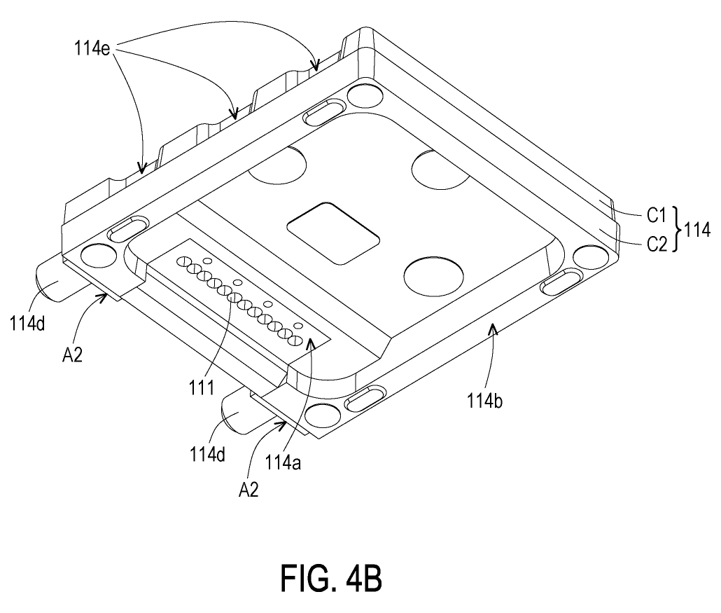

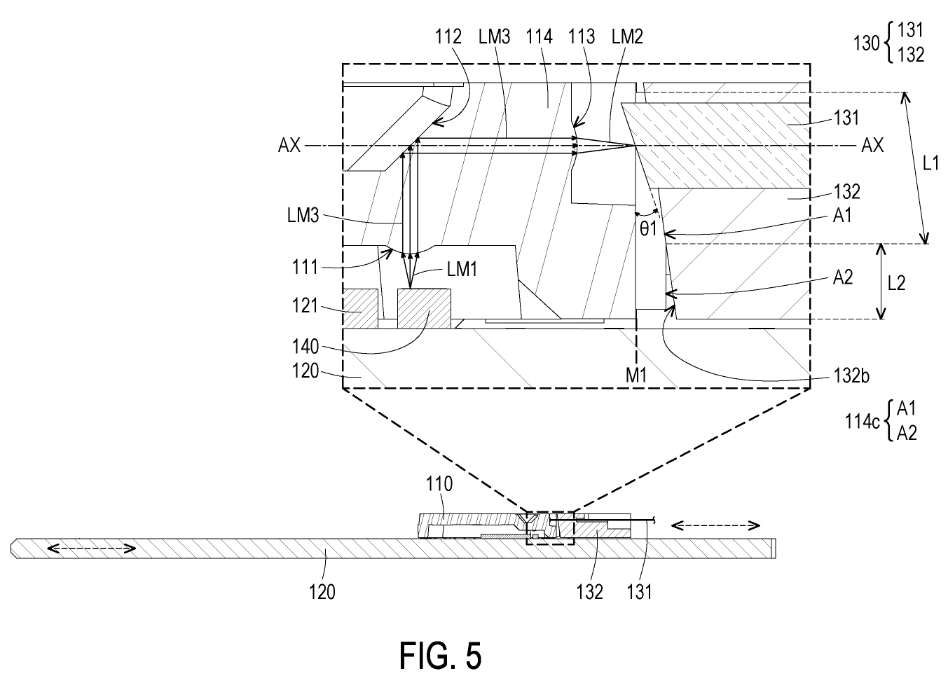

FIG. 4A is an assembly schematic view of partial components of an optical coupling lens module and a fiber jumper. FIG. 4B depicts the optical coupling lens module from another viewing angle. FIG. 5 is a cross-sectional view of the optical coupling component. Please refer to FIGS. 4A, FIG. 4B and FIG. 5, the optical coupling lens module 110 includes a body 114, a first convex lens 111, a light reflecting element 112 and a second convex lens 113. The body 114 has an inner bottom surface 114a, a positioning protrusion 114d and a docking surface 114c, wherein the positioning protrusion 114d protrudes from the docking surface 114c, the docking surface 114c includes a first abutting surface A1 and a second abutting surface A2 different from each other, and the positioning protrusion 114d occupies a portion of the first abutting surface A1 and occupies a portion of the second abutting surface A2. The first convex lens 111 is set on the inner bottom surface 114a of the body 114, the light reflecting element 112 is set within the body 114, and the second convex lens 113 is set on the outer side surface of the body 114 and is located between the two docking surfaces 114c.

Please refer to FIGS. 3, FIG. 4A and FIG. 4B again. The body 114 further has a first side F1 and a second side F2 opposite to each other, and the body 114 forms spaced recesses 114e on the first side F1 and the second side F2 respectively, and causes the body 114 to form a double-layer structure (an upper layer structure C1, a lower layer structure C2) on the first side F1 and the second side F2 respectively. The recess space of the spaced recesses 114e shown is mainly formed in the upper layer structure C1, and the lower layer structure C2 has an outer bottom surface 114b and is attached to the circuit board component 120. As shown in FIG. 4B, the double-layer structure causes the bottom of the body 114 to form an outer bottom surface 114b and an inner bottom surface 114a, wherein the body 114 rests on a board body 123 of the circuit board component 120 through the outer bottom surface 114b, and the outer bottom surface 114b surrounds the inner bottom surface 114a. The inner bottom surface 114a has a step difference in the thickness direction relative to the outer bottom surface 114b, thereby forming an enclosed space when the body 114 covers the circuit board component 120.

Furthermore, the optical coupling component 100 further includes an adhesive 160, which is filled in the spaced recesses 114e of the body 114 and bonded between the body 114 and the board body 123 of the circuit board component 120. Here, since the spaced recesses 114e have a three-dimensional space, in addition to the recess along the plane where the upper layer structure C1 is located, the lower layer structure C2 further forms a barrier at the recess of the upper layer structure C1. Therefore, when the adhesive 160 is used as the bonding medium between the optical coupling lens module 110 and the circuit board component 120, it may effectively provide three-dimensional bonding force and restraining force to the body 114 of the optical coupling lens module 110, thereby enhancing the reinforcement effect of the optical coupling lens module 110 on the circuit board component 120.

Please refer to FIGS. 4A, FIG. 4 and FIG. 5 again. Correspondingly, the fiber jumper 130 includes multiple optical fibers 131 (or referred to as fiber cores) and a body 132, wherein the positioning protrusion 114d is used to be inserted into a positioning hole 132a of the fiber jumper 130, to provide a preliminary positioning effect for the assembly and optical coupling operation of the optical coupling lens module 110 and the fiber jumper 130. Furthermore, the body 132 of the fiber jumper 130 further has a docking surface 132b, which is used to abut against the docking surface 114c, thereby providing a precise positioning effect again for the optical coupling operation. The optical coupling component 100 further includes a light source 140, configured on the board body 123 of the circuit board component 120, and the light source 140 faces the inner bottom surface 114a of the body 114. Accordingly, the optical coupling component 100 may start from the light source 140 generating a light beam, sequentially pass through the optical path formed by the first convex lens 111, the light reflecting element 112 and the second convex lens 113, and transmit the light beam to the optical fiber 131 of the fiber jumper 130. Here, the optical coupling lens module 110 is made of plastic material and through a miniaturization process, so that the first convex lens 111, the light reflecting element 112, the second convex lens 113 and the body 114 are an integrally formed structure.

Further, as shown in FIG. 5, the light source 140 is located in the enclosed space and generates a first light beam LM1 to be transmitted to the first convex lens 111, the first convex lens 111 receives the first light beam LM1 and converts it into a parallel light beam LM3, and transmits the parallel light beam LM3 to the light reflecting element 112. Then, the light reflecting element 112 reflects the parallel light beam LM3 to the second convex lens 113. Finally, the second convex lens 113 converts the parallel light beam LM3 into a second light beam LM2 and transmits it to the optical fiber 131. Thereafter, the second light beam LM2 is transmitted along the optical fiber 131. Conversely, the optical path may also be used for reverse transmission by receiving the light beam from the optical fiber 131, except that the light source 140 needs to be replaced with a light receiver (not depicted). In FIG. 5 of this embodiment, two dashed double arrows are used as illustration, wherein the dashed double arrow on the right side represents the optical signal transmission in the optical fiber 131, and the dashed double arrow on the left side represents the electrical signal transmission in the circuit board component 120.

As described above, the docking surface 114c of this embodiment includes a first abutting surface A1 and a second abutting surface A2, wherein the second abutting surface A2 adjoins the outer bottom surface 114b, and the first abutting surface A1 is away from the outer bottom surface 114b. More importantly, the first abutting surface A1 has an inclination angle of angle θ1 relative to the second abutting surface A2, and the angle θ1 is 8 degrees. As shown in FIG. 5, the second abutting surface A2 is coincident with or parallel to a reference plane M1, and the first abutting surface A1 forms an 8-degree angle (i.e., the angle θ1) relative to the reference plane M1. Here, the reference plane M1 is a normal plane of an optical axis AX of the second light beam LM2, so that the first abutting surface A1 and the second abutting surface A2 adapt to the fiber jumper 130 having contact surfaces with different angles. In this embodiment, the fiber jumper 130 has a docking surface 132b that also has an 8-degree inclination angle. Here, the angle θ1 is specifically for the beveled angle of the end face polishing of the optical fiber 131 in accordance with APC (Angled Physical Contact) connector, to guide the reflected light to the cladding rather than directly returning to the fiber core, greatly reducing return loss, thereby improving the transmission efficiency of light in the optical fiber 131. Accordingly, the body 132 of the fiber jumper 130 may dock with the first abutting surface A1 of the optical coupling lens module 110 through its docking surface 132b, to ensure that the angle θ1 may be maintained during the optical coupling operation.

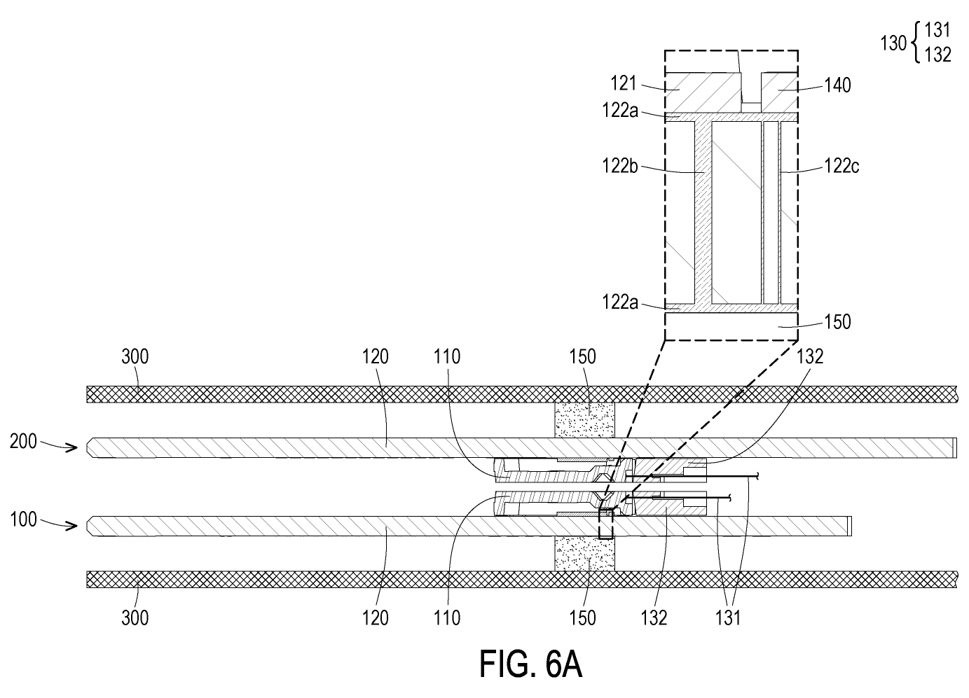

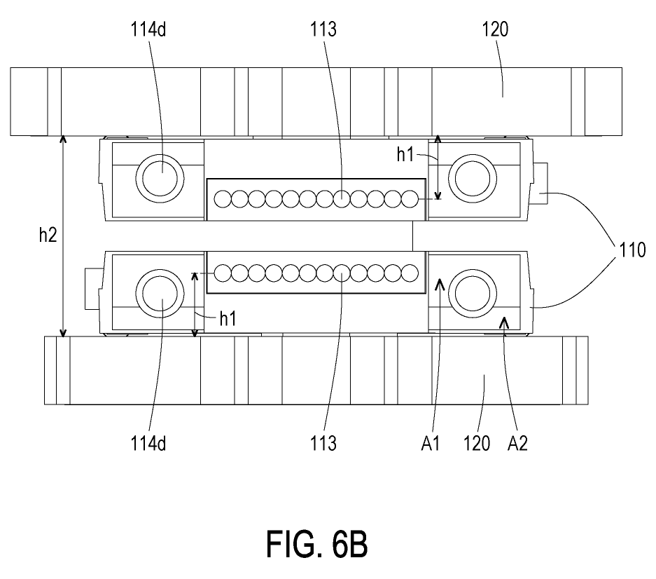

FIG. 6A is a partial cross-sectional view of the optical fiber connector. Referring to FIG. 6A, in this embodiment, the optical fiber connector 10 further includes heat conductive members 150 corresponding to the two optical coupling components 100 and 200, the two heat conductive members 150 are disposed on the two circuit board components 120 respectively and abut the metal housing 300, to transmit the heat generated by the light source 140, the optical coupling lens module 110 and the circuit board component 120 to the metal housing 300 via the heat conductive members 150. Here, the circuit board component 120 further includes an electronic processing element 121 (such as a control IC) set on the board body 123, electrically connected to the light source 140, therefore when the circuit board component 120 is in operation, the electronic processing element 121 and the light source 140 obviously constitute a heat source HT of the optical coupling component 100.

Furthermore, the circuit board component 120 of this embodiment further includes a heat conductive portion 122, which penetrates through the board body 123 and is exposed from at least one surface of the board body 123 (as shown in FIG. 6A, multiple portions 122a of the heat conductive portion 122 are respectively exposed from the upper and lower surfaces of the board body 123), and the heat conductive member 150 abuts the portion 122a exposed from the board body 123. Meanwhile, the heat conductive portion 122 of this embodiment may form a column structure 122b or a tube structure 122c when penetrating through the board body 123 for heat transfer purposes. In this way, the heat generated from the heat source HT may be transmitted to the heat conductive member 150 via the portion 122a and the column structure 122b or tube structure 122c of the heat conductive portion 122, and accordingly transmitted to the metal housing 300 to dissipate to the external environment. Here, the heat conductive portion 122 may be formed together with copper material when manufacturing the circuit board component 120, to improve the manufacturing efficiency of the circuit board component 120.

Referring to FIGS. 6A versus FIG. 2, as described above, this embodiment adopts a specific stacking method, that is, along the longitudinal direction V1 in which the two optical coupling components 100 and 200 are stacked, the optical coupling lens module 110 and the fiber jumper 130 are located at the center of the internal space of the metal housing 300 and positioned between the two circuit board components 120, so that the above heat dissipation mechanism may be effectively utilized to achieve rapid heat dissipation effect. Conversely, if the stacking structure of this embodiment is not adopted, it is obvious that additional heat conductive paths in other directions need to be provided to have the opportunity to achieve rapid heat dissipation effect, but this obviously requires additional component configuration space, therefore it may be known that the stacking structure of this case may provide a more compact structural configuration for the optical fiber connector 10, and also has a rapid heat dissipation mechanism. Here, through the miniaturization manufacturing of the optical coupling lens modules 110 and 200, the relative distance between the centers of the board bodies 123 of the two circuit board components 120 is less than 3.5mm.

FIG. 6B depicts the optical fiber connector from another viewing angle, which observes the optical coupling lens module 110 from the opposite side of the docking side R1, and omits the fiber jumper 130, to facilitate identification of the second convex lens 113. Referring to FIG. 6B, in this embodiment, the second convex lens 113 has a height h1 relative to the circuit board component 120, and also due to the stacking structure of the two optical coupling components 100 adopted in this embodiment, a spacing h2 between the two circuit board components 120 may be ensured accordingly. Here, the height h1 of this embodiment is preferably less than or equal to 1.3mm, and therefore may adapt to the stacking structure with spacing h2 greater than or equal to 2.85mm.

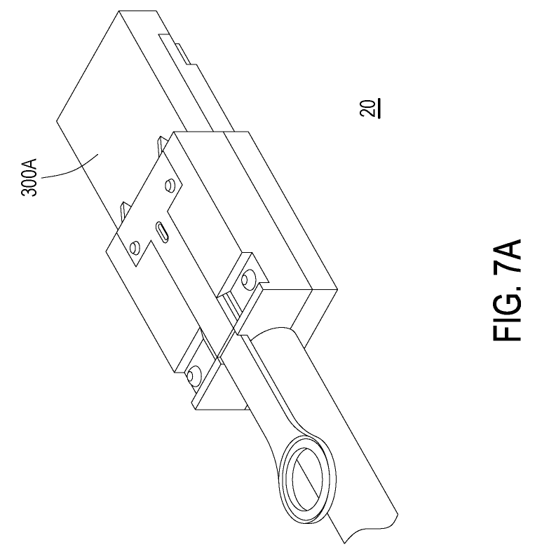

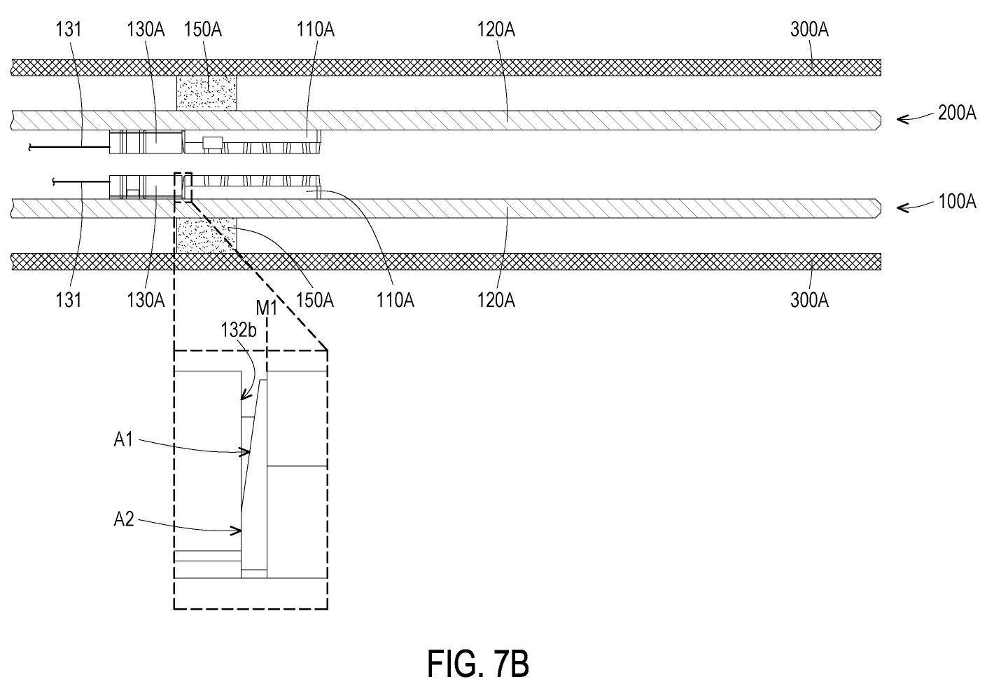

FIG. 7A depicts an optical fiber connector according to another embodiment of the disclosure. FIG. 7B is a side view of partial components of the optical fiber connector of FIG. 7A. Referring to FIGS. 7A and FIG. 7B simultaneously, an optical fiber connector 20 disclosed in this embodiment belongs to a CDFP (Compact Data Center Form Factor) connector, which is a high-density external interface designed for high-speed data transmission, specifically used for data center and other applications, supporting 400Gbps (or higher) single-port transmission rate, utilizing multi-channel (16 channels) to achieve ultimate space utilization and bandwidth. Therefore, the optical fiber connector 20 also adopts the same double-layer stacking structure as the aforementioned embodiment. In optical coupling components 100A and 200A of this embodiment, they similarly configure the optical coupling lens module 110A and a fiber jumper 130A at the center of the internal space of a metal housing 300A along the longitudinal direction V1, and positioned between two circuit board components 120A, to facilitate the other side of the two circuit board components 120A to respectively abut the inner wall of the metal housing 300A through a heat conductive member 150A, generating the same heat dissipation path as the aforementioned embodiment. This also makes the relative distance between the board body centers of the circuit board components 120A less than 3.0mm due to the compact stacking structure.

However, different from the aforementioned embodiment, the docking surface 132b of the fiber jumper 130A in this embodiment abuts the second abutting surface A2 of the optical coupling lens module 110A, that is, a docking mode with 0 degree and no inclination relative to a reference plane M1. It should also be mentioned that, in response to current optical fiber specifications, the ratio of dimension L1 to dimension L2 of the first abutting surface A1 and the second abutting surface A2 in this embodiment is preferably 2.3:1.

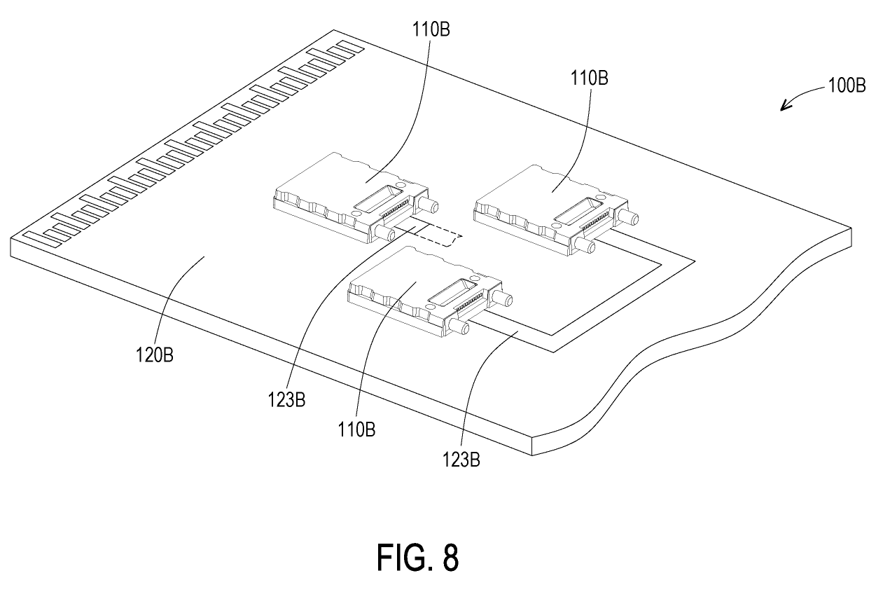

FIG. 8 is a partial schematic view of an optical coupling component according to another embodiment of the disclosure. Referring to FIG. 8, as mentioned above, due to the miniaturization fabrication of the optical coupling lens module 110, it may provide different configuration methods when matched with related structures. FIG. 8 shows providing a larger circuit board component 120B so that it may carry multiple optical coupling lens modules 110B, and may configure corresponding circuits 123B according to requirements. In other words, in response to the miniaturization of the optical coupling lens module 110B, the design freedom within the optical fiber connector may be increased accordingly, to adjust the corresponding relationship between the optical coupling lens module 110B and peripheral components according to different requirements, improving its adaptability.

In summary, in the embodiments of this disclosure, the body of the optical coupling lens module provides a first abutting surface and a second abutting surface that are different from each other on its docking surface having positioning protrusions, to facilitate adapting to different angle interfaces of different fiber jumpers. Meanwhile, for the optical fiber connector, particularly for the space configuration in a double-layer circuit board stacking state, the two optical coupling lens modules of the optical coupling component adjoin each other and are away from the metal housing, while the two circuit board components of the optical coupling component are opposite to each other with the two optical coupling lens modules therebetween to be adjacent to the metal housing. This provides better space utilization through compact configuration.

More importantly, based on the stacking structure, heat conductive members are further incorporated, and the heat conductive members are respectively configured on the side of the circuit board components facing the metal housing, thereby abutting on the circuit board components and on the inner wall of the metal housing. Accordingly, the heat generated from the light sources and the circuit board components may be transmitted to the metal housing via the heat conductive members, which provides the shortest heat dissipation path, so that the optical coupling component achieves rapid heat dissipation effect due to the stacking structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An optical coupling lens module, comprising:
a body, having an inner bottom surface, a positioning protrusion, and a docking surface, wherein the positioning protrusion protrudes from the docking surface to adapt to dock with a fiber jumper, the docking surface comprising a first abutting surface and a second abutting surface different from each other to adapt to the fiber jumper, the positioning protrusion occupying a portion of the first abutting surface and occupying a portion of the second abutting surface;
a first convex lens, disposed on the inner bottom surface to receive a first light beam from a light source and convert the first light beam to a parallel light beam;
a light reflecting element, disposed in the body to receive and transmit the parallel light beam; and
a second convex lens, disposed on an outer surface of the body, to receive the parallel light beam and convert the parallel light beam to a second light beam and transmit the second light beam to a fiber core of the fiber jumper.

2. The optical coupling lens module according to claim 1, wherein the body further has a first side and a second side opposite to each other, and the body forms spaced recesses on the first side and the second side respectively, and causes the body to form a double-layer structure on the first side and the second side respectively.

3. The optical coupling lens module according to claim 1, wherein the body further has an outer bottom surface, surrounding the inner bottom surface and configured to rest on a circuit board component, the light source is disposed on the circuit board component to face the first convex lens.

4. The optical coupling lens module according to claim 3, wherein the second abutting surface adjoins the outer bottom surface, the first abutting surface is away from the outer bottom surface.

5. The optical coupling lens module according to claim 1, wherein the second abutting surface is coincident with or parallel to a reference plane, the first abutting surface forms an 8-degree angle relative to the reference plane, the reference plane is a normal plane of an optical axis of the second light beam, such that the first abutting surface and the second abutting surface adapt to the fiber jumper having contact surfaces with different angles.

6. An optical fiber connector, comprising:
a metal housing;
two optical coupling components, disposed in the metal housing, each of the optical coupling components comprising:
an optical coupling lens module, comprising:
a body, having an inner bottom surface, a positioning protrusion, and a docking surface, wherein the positioning protrusion protrudes from the docking surface, the docking surface comprising a first abutting surface and a second abutting surface different from each other, the positioning protrusion occupying a portion of the first abutting surface and occupying a portion of the second abutting surface;
a first convex lens, disposed on the inner bottom surface;
a light reflecting element, disposed in the body;
a second convex lens, disposed on the docking surface;
a light source;
a fiber jumper; and
a circuit board component, the light source, the fiber jumper, and the body being respectively disposed on the circuit board component,
wherein the two optical coupling lens modules of the two optical coupling components adjoin each other and are away from the metal housing, the two circuit board components of the two optical coupling components are opposite to each other with the two optical coupling lens modules therebetween to be adjacent to the metal housing, wherein the light source generates a light beam sequentially transmitted through the first convex lens, the light reflecting element, and the second convex lens to the fiber jumper.

7. The optical fiber connector according to claim 6, further comprising two heat conductive members, separately disposed on the two circuit board components and abutting the metal housing, to transmit heat generated by the light source, the optical coupling lens module, and the circuit board component to the metal housing through the heat conductive members.

8. The optical fiber connector according to claim 7, wherein the circuit board component comprises a board body and a heat conductive portion, the heat conductive portion penetrates through the board body and is exposed from at least one surface of the board body, and the heat conductive member abuts on the heat conductive portion exposed from the board body.

9. The optical fiber connector according to claim 6, wherein a center-to-center distance between the two circuit board components is less than 3.0mm.

10. The optical fiber connector according to claim 6, wherein a center-to-center distance between the two circuit board components is less than 3.5mm.

11. The optical fiber connector according to claim 6, wherein the body further has a first side and a second side opposite to each other, and the body forms spaced recesses on the first side and the second side respectively, and causes the body to form a double-layer structure on the first side and the second side respectively.

12. The optical fiber connector according to claim 11, wherein the optical coupling component further comprises an adhesive, filled in the spaced recesses and bonded between the body and the circuit board component.

13. The optical fiber connector according to claim 6, wherein the body further has an outer bottom surface, surrounding the inner bottom surface and configured to rest on the circuit board component, the light source is disposed on the circuit board component to face the first convex lens.

14. The optical fiber connector according to claim 13, wherein the second abutting surface adjoins the outer bottom surface, and the first abutting surface is away from the outer bottom surface.

15. The optical fiber connector according to claim 6, wherein the second abutting surface is coincident with or parallel to a reference plane, the first abutting surface forms an 8-degree angle relative to the reference plane, the reference plane is a normal plane of an optical axis of the light beam entering the fiber jumper, such that the first abutting surface and the second abutting surface adapt to the fiber jumper having contact surfaces with different angles.

16. The optical fiber connector according to claim 6, wherein the second convex lens has a height (h1) relative to the circuit board component, to adapt to the optical fiber connector stacked by the two circuit board components having a spacing (h2), the height (h1) ≤ 1.3mm, the spacing (h2) ≥ 2.85mm.
